(19) United States
(12) Patent Application Publication
(10) Pub. No.: US 2015/0241797 A1
(43) Pub. Date: Aug. 27, 2015

(54) Reticle Cleaning by Means of Sticky Surface

(71) Applicants: ASML Netherlands B.V., Veldhoven (NL); ASML Holding N.V., Veldhoven (NL)

(72) Inventors: Johannes Onvlee, 's-Hertogenbosch (NL); Christopher J. Mason, Newtown, CT (US); Peter A. Delmastro, New Milford, CT (US); Sanjeev Kumar Singh, Danbury, CT (US); Ronald Peter Albright, Norwalk, CT (US)

(73) Assignees: ASML Netherlands B.V., Veldhoven (NL); ASML Holding N.V., Veldhoven (NL)

(21) Appl. No.: 14/423,089

(22) PCT Filed: Jul. 30, 2013
(86) PCT No.: PCT/EP2013/065966

§ 371 Date: Feb. 20, 2015

Related U.S. Application Data
(60) Provisional application No. 61/702,932, filed on Sep. 19, 2012.
(60) Provisional application No. 61/699,745, filed on Sep. 11, 2012.
(60) Provisional application No. 61/695,973, filed on Aug. 31, 2012.

(51) Int. Cl. G03F 7/20; B08B 7/00

(52) U.S. Cl. CPC G03F 7/70925; B08B 7/0028

(57) ABSTRACT

Methods and systems are described for cleaning contamination from the surface of an object within a lithographic apparatus. A lithographic apparatus is provided that includes an illumination system configured to condition a radiation beam, a support constructed to hold a patterning device (302), the patterning device being capable of imparting the radiation beam with a pattern in its cross-section to form a patterned radiation beam, a substrate table constructed to hold a substrate, and a projection system configured to project the patterned radiation beam onto a target portion of the substrate. The lithographic apparatus further includes a cleaning system (500) for cleaning particles off of a surface of either the support or the patterning device. The cleaning system includes a cleaning surface (502) designed to contact the surface of either the support or the patterning device.

### CROSS-REFERENCE TO RELATED APPLICATIONS

This application claims the benefit of U.S. provisional application 61/695,973, which was filed on 31 Aug. 2012 and U.S. provisional application 61/699,745, which was filed on 11 Sep. 2012 and U.S. provisional application 61/702,932, which was filed on 19 Sep. 2012, which are incorporated herein in its entirety by reference.

### FIELD

The present invention relates to methods and systems for cleaning a patterning device such as a reticle or mask inside a lithography apparatus.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{NA} \qquad ( 1 )$$

where λ is the wavelength of the radiation used, NA is the numerical aperture of the projection system used to print the pattern, k1 is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 5-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

EUV radiation may be produced using a plasma. A radiation system for producing EUV radiation may include a laser for exciting a fuel to provide the plasma, and a source collector module for containing the plasma. The plasma may be created, for example, by directing a laser beam at a fuel, such as droplets of a suitable fuel material (e.g., tin, which is currently thought to be the most promising and thus likely choice of fuel for EUV radiation sources), or a stream of a suitable gas or vapor, such as Xe gas or Li vapor. The resulting plasma emits output radiation, e.g., EUV radiation, which is collected using a radiation collector. The radiation collector may be a mirrored normal incidence radiation collector, which receives the radiation and focuses the radiation into a beam. The source collector module may include an enclosing structure or chamber arranged to provide a vacuum environment to support the plasma. Such a radiation system is typically termed a laser produced plasma (LPP) source. In an alternative system, which may also employ the use of a laser, radiation may be generated by a plasma formed by the use of an electrical discharge—a discharge produced plasma (DPP) source.

An electrostatic chuck (ESC) used in a lithography apparatus to hold a patterning reticle on a scanning stage can become contaminated. This contamination can be transferred from the reticle to the ESC and vice versa. The contamination can also originate in the lithographic chamber itself. The contamination causes overlay error and therefore nonfunctional computer chips. Additionally, this contamination may be found on the patterned side of the patterning device itself. The contamination may be transferred to the patterning device from a POD that is used to transport the patterning device within the lithographic apparatus.

Typically, the ESC is manually cleaned. However, the current cleaning leaves a residue of very fine particles. The manual cleaning typically only remove particles larger than approximately 3 μm in diameter. Manual cleaning requires the apparatus to be vented to atmospheric pressure and partially disassembled, which in turn causes loss of productivity.

The state of the art for cleaning an ESC in situ of the lithography tool is a manual solvent wipe with a special reduced particulate wiper. It is not possible to remove the ESC for ex situ traditional wet cleaning since it is electrically and mechanically into a monolithic machine component.

In semiconductor micro lithography, there are systems where the reticle may be reflective or transmissive and clamped to a surface. Typically, reflective reticles are clamped on a backside opposite from a surface containing the patterned features while transmissive reticles are clamped around the outer edges of the side having the patterned features. These clamped surfaces must be clean in order to obtain a reasonable yield in chip production. Thus, a user needs to be able to clean the clamp and/or patterning device if either becomes contaminated.

### SUMMARY

It is desirable to obviate or mitigate at least one of the problems, whether identified herein or elsewhere, or to provide an alternative to existing apparatus or methods.

According to a first aspect of the present invention, there is provided a method for removing particles from a surface of an object within a lithographic apparatus that includes contacting the surface of the object with a cleaning surface. The method includes transferring particles on the object to the cleaning surface and separating the cleaning surface from the surface of the object, the particles being adhered to the cleaning surface.

According to a second aspect of the present invention, there is provided a lithographic apparatus that includes an illumination system configured to condition a radiation beam, a support constructed to hold a patterning device, the patterning device being capable of imparting the radiation beam with a pattern in its cross-section to form a patterned radiation beam, a substrate table constructed to hold a substrate, and a projection system configured to project the patterned radiation beam onto a target portion of the substrate. The lithographic apparatus further includes a cleaning system for cleaning particles off of a surface of either the support or the patterning device. The cleaning system includes a cleaning surface designed to contact the surface of either the support or the patterning device.

Further features and advantages of the present invention, as well as the structure and operation of various embodiments of the present invention, are described in detail below with reference to the accompanying drawings. It is noted that the present invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the present invention and to enable a person skilled in the relevant art(s) to make and use the present invention.

FIG. 1 shows a lithographic apparatus according to an embodiment of the present invention.

FIG. 2 is a more detailed view of the apparatus of FIG. 1, including an LPP source collector module, according to an embodiment.

FIG. 3 shows a lithographic apparatus according to another embodiment of the present invention.

FIG. 4 illustrates a side view of a patterning device supported on a structure, according to an embodiment.

FIGS. 5A and 5B illustrate a top view and a side view of a patterning device with particle contamination, according to an embodiment.

FIG. 6 illustrates a cleaning system, according to an embodiment.

FIG. 7 illustrates an operation of the cleaning system, according to an embodiment.

FIG. 8 illustrates another embodiment of the cleaning system.

FIG. 9 illustrates another embodiment of the cleaning system.

FIG. 10 illustrates an example method, according to an embodiment.

FIG. 11 illustrates an example method, according to an embodiment.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

This specification discloses one or more embodiments that incorporate the features of this invention. The disclosed embodiment(s) merely exemplify the present invention. The scope of the present invention is not limited to the disclosed embodiment(s). The present invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the present invention may be implemented in hardware, firmware, software, or any combination thereof. Embodiments of the present invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

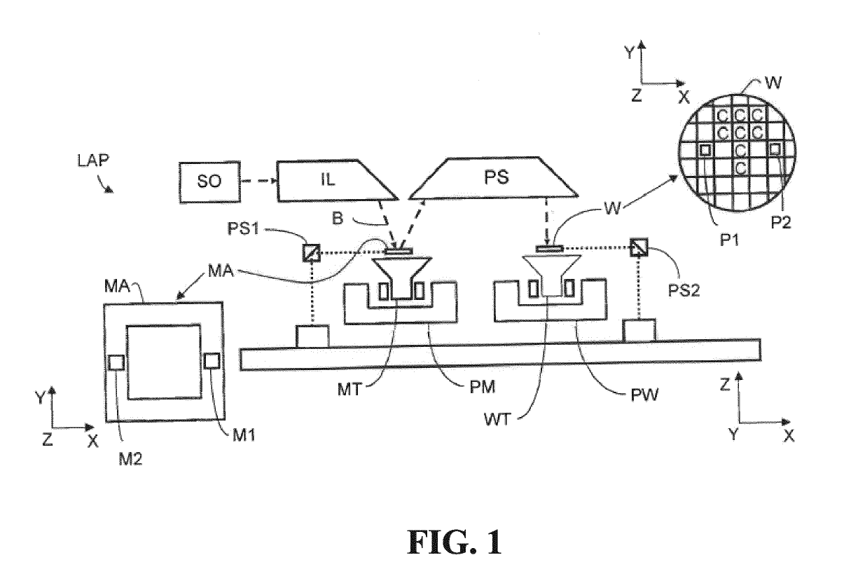

FIG. 1 schematically shows a lithographic apparatus LAP including a source collector module SO according to an embodiment of the present invention. The apparatus comprises: an illumination system (illuminator) IL configured to condition a radiation beam B (e.g., EUV radiation); a support structure (e.g., a mask table) MT constructed to support a patterning device (e.g., a mask or a reticle) MA and connected to a first positioner PM configured to accurately position the patterning device; a substrate table (e.g., a wafer table) WT constructed to hold a substrate (e.g., a resist-coated wafer) W and connected to a second positioner PW configured to accurately position the substrate; and a projection system (e.g., a reflective projection system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam that is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since gases may absorb too much radiation. A vacuum environment may therefore be provided to the whole beam path with the aid of a vacuum wall and vacuum pumps.

As here depicted, the apparatus is of a reflective type (e.g., employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives an extreme ultra violet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam and exciting the fuel. The resulting plasma emits output radiation, e.g., EUV radiation, which is collected using a radiation collector, disposed in the source collector module. The laser and the source collector module may be separate entities, for example when a CO₂ laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using mask alignment marks M1, M2 and substrate alignment marks P1, P2.

The depicted apparatus could be used in at least one of the following modes:

1. In step mode, the support structure (e.g., mask table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.

2. In scan mode, the support structure (e.g., mask table) MT and the substrate table WT are scanned synchronously while a pattern imparted to the radiation beam is projected onto a target portion C (i.e., a single dynamic exposure). The velocity and direction of the substrate table WT relative to the support structure (e.g., mask table) MT may be determined by the (de-)magnification and image reversal characteristics of the projection system PS.

3. In another mode, the support structure (e.g., mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

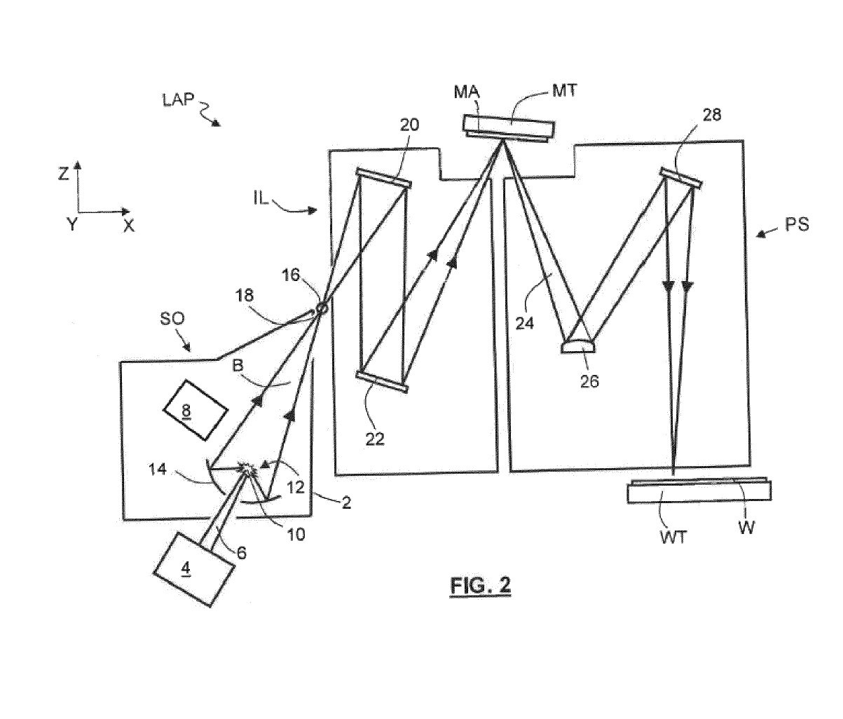

FIG. 2 shows the lithographic apparatus LAP in more detail, including the source collector module SO, the illumination system IL, and the projection system PS. The source collector module SO is constructed and arranged such that a vacuum environment can be maintained in an enclosing structure 2 of the source collector module.

A laser 4 is arranged to deposit laser energy via a laser beam 6 into a fuel, such as xenon (Xe), tin (Sn) or lithium (Li) that is provided from a fuel supply 8 (sometimes referred to as a fuel stream generator). Tin, or another molten metal or intermetallic (most likely in the form of droplets) is currently thought to be the most promising and thus likely choice of fuel for EUV radiation sources. The deposition of laser energy into the fuel creates a highly ionized plasma 10 at a plasma formation location 12 that has electron temperatures of several tens of electronvolts (eV). The energetic radiation generated during de-excitation and recombination of these ions is emitted from the plasma 10, collected and focussed by a near normal incidence radiation collector 14. A laser 4 and a fuel supply 8 (and/or a collector 14) may together be considered to comprise a radiation source, specifically an EUV radiation source. The EUV radiation source may be referred to as a laser produced plasma (LPP) radiation source.

A second laser (not shown) may be provided, the second laser being configured to preheat the fuel before the laser beam 6 is incident upon it. An LPP source that uses this approach may be referred to as a dual laser pulsing (DLP) source.

Although not shown, the fuel stream generator will comprise, or be in connection with, a nozzle configured to direct a stream of fuel droplets along a trajectory towards the plasma formation location 12.

Radiation B that is reflected by the radiation collector 14 is focused at a virtual source point 16. The virtual source point 16 is commonly referred to as the intermediate focus, and the source collector module SO is arranged such that the intermediate focus 16 is located at or near to an opening 18 in the enclosing structure 2. The virtual source point 16 is an image of the radiation emitting plasma 10.

Subsequently, the radiation B traverses the illumination system IL, which may include a facetted field mirror device 20 and a facetted pupil mirror device 22 arranged to provide a desired angular distribution of the radiation beam B at the patterning device MA, as well as a desired uniformity of radiation intensity at the patterning device MA. Upon reflection of the beam of radiation at the patterning device MA, held by the support structure MT, a patterned beam 24 is formed and the patterned beam 24 is imaged by the projection system PS via reflective elements 26, 28 onto a substrate W held by the wafer stage or substrate table WT.

More elements than shown may generally be present in the illumination system IL and projection system PS. Furthermore, there may be more mirrors present than those shown in the figures, for example there may be 1-6 additional reflective elements present in the projection system PS than shown in FIG. 2.

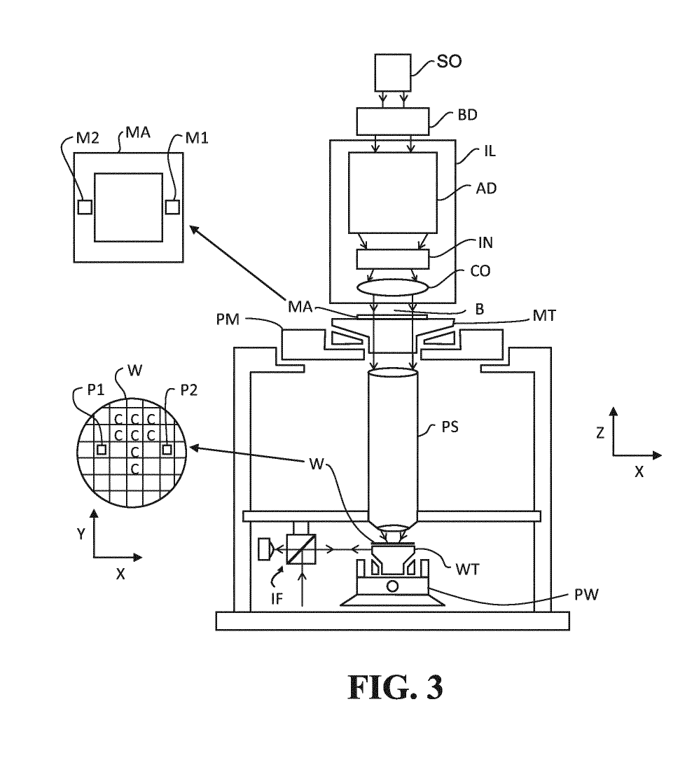

FIG. 3 schematically shows a lithographic apparatus LAP including a source collector module SO according to another embodiment of the invention. The apparatus includes: an illumination system (illuminator) IL configured to condition a radiation beam B (e.g., EUV radiation); a support structure (e.g., a mask table) MT constructed to support a patterning device (e.g., a mask or a reticle) MA and connected to a first positioner PM configured to accurately position the patterning device; a substrate table (e.g., a wafer table) WT constructed to hold a substrate (e.g., a resist-coated wafer) W and connected to a second positioner PW configured to accurately position the substrate; and a projection system (e.g., a reflective projection system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e., bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 3, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross section.

The radiation beam B is incident on the patterning device (e.g., mask MA), which is held on the support structure (e.g., mask table MT), and is patterned by the patterning device. Having traversed the mask MA, the radiation beam B passes through the projection system PS, which focuses the beam onto a target portion C of the substrate W. With the aid of the second positioner PW and position sensor IF (e.g., an interferometric device, linear encoder or capacitive sensor), the substrate table WT can be moved accurately, e.g., so as to position different target portions C in the path of the radiation beam B. Similarly, the first positioner PM and another position sensor (which is not explicitly depicted in FIG. 3) can be used to accurately position the mask MA with respect to the path of the radiation beam B, e.g., after mechanical retrieval from a mask library, or during a scan. In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:

1. In step mode, the mask table MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the mask table MT and the substrate table WT are scanned synchronously while a pattern imparted to the radiation beam is projected onto a target portion C (i.e., a single dynamic exposure). The velocity and direction of the substrate table WT relative to the mask table MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the mask table MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

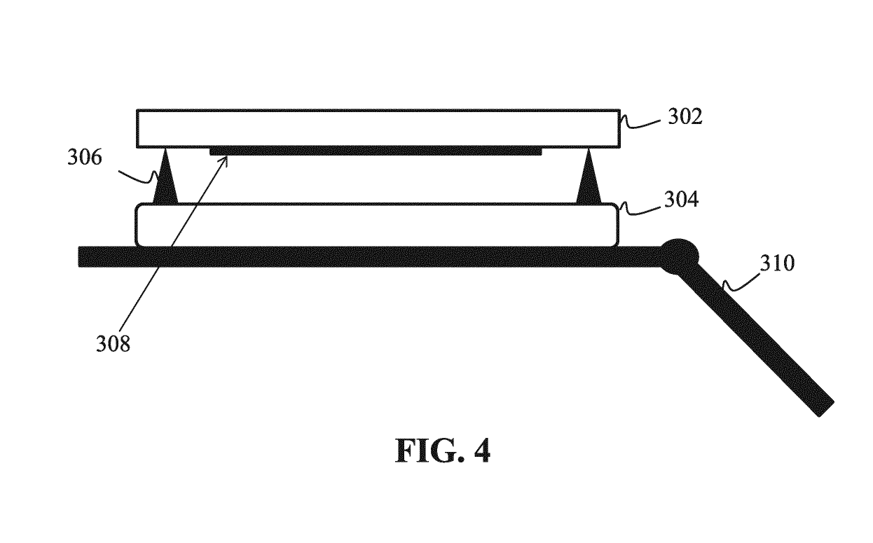

FIG. 4 shows an example of a patterning device 302 supported on a structure 304. The structure may be a POD as is known by those having skill in the relevant art(s) for transporting patterning device 302 within a lithographic apparatus. Structure 304 may itself be transported via arm 310.

In one example, patterning device 302 is a reticle, such as a reflective reticle, having an array of patterned elements. The patterned elements may be disposed on a patterned side 308 of patterning device 302. In another example, patterned side 308 represents etched features of an optical mask to be used for contact or projection lithography.

It should be understood that patterning device 302 may make contact at or around its edges to various structures either within the lithographic apparatus or outside when being stored. For example, patterning device 302 may be held in a cassette structure or case when not being used for exposures. Any of the various structures that make contact to either the backside or patterned side 308 of patterning device 302 may contaminate the surface at or near where the contact is made.

In an embodiment, patterning device 302 rests upon raised features 306 associated with structure 304. This may be to protect patterned side 308 as patterning device 302 is being transported. Due to this contact, contamination may be transferred to patterned side 308 of patterning device 302 via the contact points with raised features 306. The contamination may be in the form of particles left behind on patterning device 302. The contamination may result in reticle deformation and imaging abnormalities. It should be understood that patterning device 302 may be supported from any angle or side and is not limited to the support mechanism illustrated in FIG. 3. For example, patterning device 302 may be supported from the sides or on its corners, and contamination may be transferred at these various points of contact.

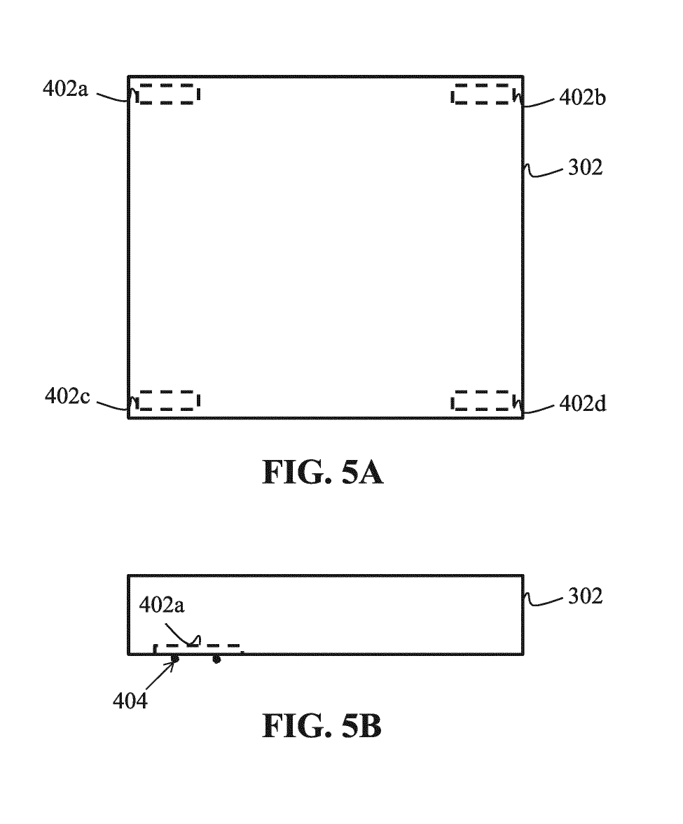

FIG. 5A illustrates a top view of patterning device 302 with various contact points 402a-d shown, according to an embodiment. Contact points 402a-d represent areas that were in physical contact with raised features 306 of structure 304. In another example, contact points 402a-d represent areas that were in contact with any other object that could transfer contamination to patterning device 302. It should be understood that the illustrated locations of contact points 402a-d are not intended to be limiting, and that contact may be made anywhere on the surface of patterning device 302.

FIG. 5B illustrates a side view of patterning device 302 showing one of the contact points 402a and contamination 404 present on the surface, according to an embodiment. Contamination 404 may be in the form of particles that have been transferred via contact with another structure at contact point 402a.

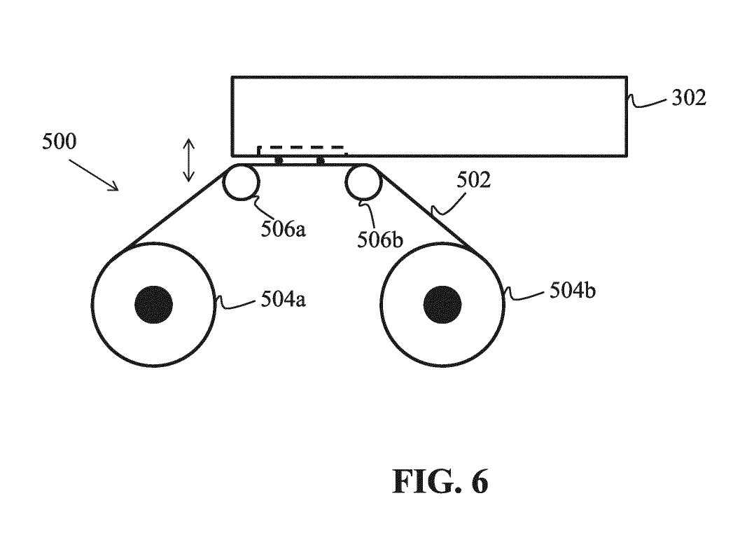

FIG. 6 illustrates a cleaning system 500, according to an embodiment. Cleaning system 500 includes a layer of tape 502, at least two rolls 504a and 504b and one or more support rolls 506a and 506b. It should be understood, however, that cleaning system 500 may include more than two rolls 504 and any number of support rolls 506.

In an embodiment, layer of tape 502 includes an adhesive tape designed to capture particles present on the surface of patterning device 302. Layer of tape 502 is stretched between rolls 504a and 504b and is similar in design to, for example, a cassette tape.

Rolls 504a and 504b may be the same size or different sizes. In an embodiment, roll 504a may be used as a source of the layer of tape 502 while roll 504b collects the “used” tape after it has contacted a surface to clean off any present contamination. In an embodiment, layer of tape 502 is spooled around each of rolls 504a and 504b.

Cleaning system 500 may include various replaceable elements. For example, roll 504a may be easily replaced with a new roll containing a newly spooled layer of tape. Similarly, roll 504b may be replaced with a blank roll for collecting the new layer of tape. In one example, rolls 504a and 504b are linked in a single cassette structure and are removed together and replaced with a new cassette that contains new rolls 504a and 504b. In another example, rolls 504a and 504b remain unchanged within cleaning system 500 while a new layer of tape is fed onto either of the rolls for further use.

Support rolls 506a and 506b may be included to support layer of tape 502 and generate a flat portion of layer of tape 502. This flat portion comes into contact with a contaminated surface of patterning device 302, according to an embodiment. Although two support rolls are illustrated, it should be understood that any number of support rolls may be included within cleaning system 500.

Cleaning system 500 may be included at each location around patterning device 302 where a contact point is made. In another example, a single cleaning system 500 may be included in a lithographic apparatus, where the single system is moved around to clean various surfaces. In yet another example, one or more cleaning systems may remain stationary while patterning device 302 is moved over them to clean the surface of patterning device 302. Either patterning device 302 is brought into contact with layer of tape 502 or layer of tape 502 is brought into contact with a surface of patterning device 302, according to different embodiments. When contact is made, particles present are transferred to layer of tape 502. After separating cleaning system 500 and patterning device 302, the particles will remain captured on layer of tape 502. In one example, layer of tape 502 may be advanced while cleaning system 500 is moved across the surface of patterning device 302. In this way, a fresh area of tape can be exposed at all times to the surface. In an embodiment, layer of tape 502 leaves behind no residue upon the surface of patterning device 302. Layer of tape 502 may be a sticky tape such as, for example, a KAPTON or polyimide tape that leaves behind no residue. In another embodiment, layer of tape may be an insulating material that is charged to attract particle contamination via electrostatic interactions.

It should be understood that although the above description is for cleaning contamination off of a patterning device, the invention should not be limited in such a way. For example, cleaning system 500 may also be used to clean contamination off of a chuck or support that is used to hold patterning device 302. The chuck may be an electrostatic chuck that uses an applied voltage to clamp to patterning device 302. Surfaces of other structures within a lithographic apparatus may be cleaned as well as would be understood by one having skill in the relevant art(s) given the description herein. Additionally, cleaning system 500 may be used to clean either a patterned side or a backside of a reticle. When cleaning the patterned side, cleaning system 500 may be restricted to cleaning areas near the edges of patterning device 302 and not the center portion that includes the patterned features. Furthermore, the areas near the edges of the patterned side may become contaminated for some reticle designs (e.g., non-EUV reticles) that are clamped from their patterned side via a vacuum chuck. Backside cleaning may be especially useful for EUV reticles that are clamped to a chuck from their backside. As such, alignment may be affected for both EUV reticles and non-EUV reticles based on contamination present on their backside or patterned side respectively.

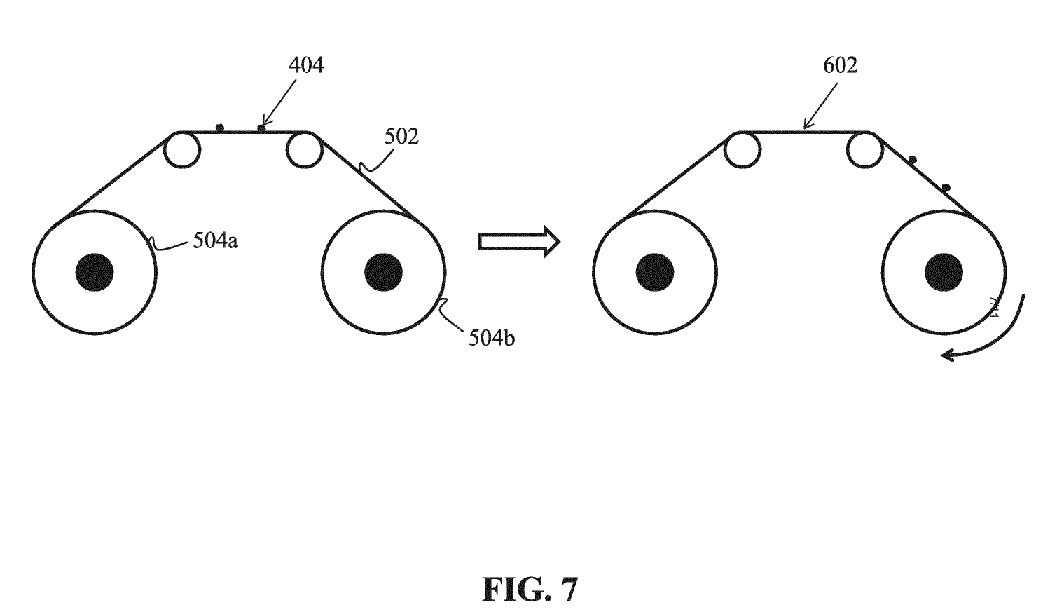

FIG. 7 illustrates an example operation of cleaning system 500, according to an embodiment. For ease of explanation, and without limitation, reference is made to elements shown in FIGS. 4 to 6. After layer of tape 502 has captured contamination 404 and cleaning system 500 is no longer in contact with any other surfaces, roll 504b may be actuated to rotate and advance layer of tape 502 to expose a fresh surface 602, according to an embodiment. Roll 504b may be actuated via a motor (not shown). In another example, both rolls 504a and 504b are actuated via one or more motors to advance layer of tape 502. In this way, fresh layer of tape 602 may be exposed for each time that layer of tape 502 is contacted to a surface for cleaning contamination from the surface.

In one example, a same area of a surface may be cleaned repeatedly by contacting the area with layer of tape 502, separating from the area, advancing to fresh layer of tape 602, and re-contacting the area with the fresh tape layer. This process may be repeated as many times as necessary to adequately clean the surface of contamination.

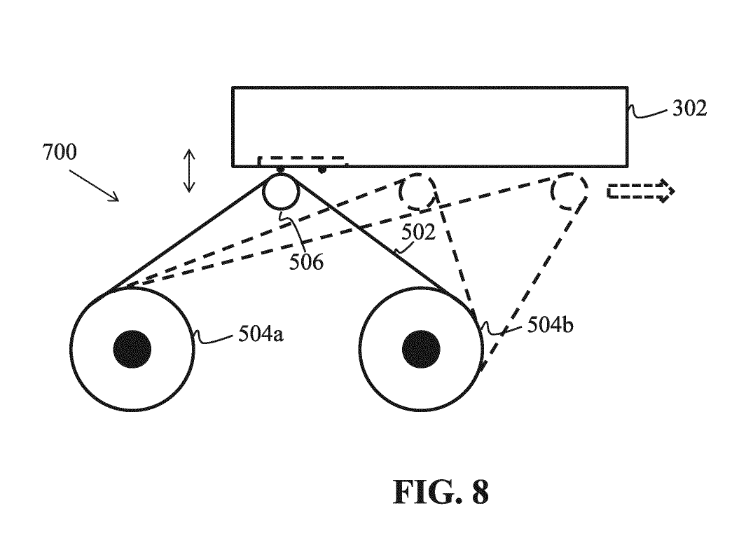

FIG. 8 illustrates another embodiment of cleaning system 700. In this example, cleaning system 700 only includes a single support roll 506 disposed between rolls 504a and 504b. Layer of tape 502 is wound between rolls 504a and 504b and stretched over support roll 506. Similar to earlier embodiments, cleaning system 700 may be raised or lowered towards the surface of patterning device 302 to clean particles off of the surface. Alternatively, patterning device 302 may be raised or lowered onto layer of tape 502 while cleaning system 700 remains stationary.

Layer of tape 502 may be mounted on the single support roll 506 adjacent the planar side of the patterning device 302 such that the single support roll 506 is configured to support layer of tape 502 to make a contact with the surface of patterning device 302 for removing particles therefrom. The surface may be the backside of the patterning device 302 such as a reflective reticle or an area on a patterned side of the patterning device 302 (e.g., a transmissive reticle) which is clamped by a vacuum clamp.

The single support roll 506 may be configured to laterally or horizontally move adjacent the surface of patterning device 302, as indicated by two positions of single support roll 506 being shown as dotted structures in FIG. 7.

In an embodiment, the single support roll 506 is moved along the surface of patterning device 302 while exposing a fresh layer of the tape 502 with no particles present on the fresh layer of tape 502. In this way, particles present on the surface of patterning device 302 transfer to the sticky layer of the tape 502. In one example, single support roll 506 may move layer of tape 502 away from the surface of patterning device 302 before advancing layer of tape 502 to expose a fresh layer.

The use of only a single support roll 506 may be advantageous in certain circumstances, as it provides a finer control of the surface to be cleaned. Additionally, the smaller contact area afforded by using a single support roll 506 increases the applied pressure between layer of tape 502 and the surface of patterning device 302, which may result in a better cleaning performance.

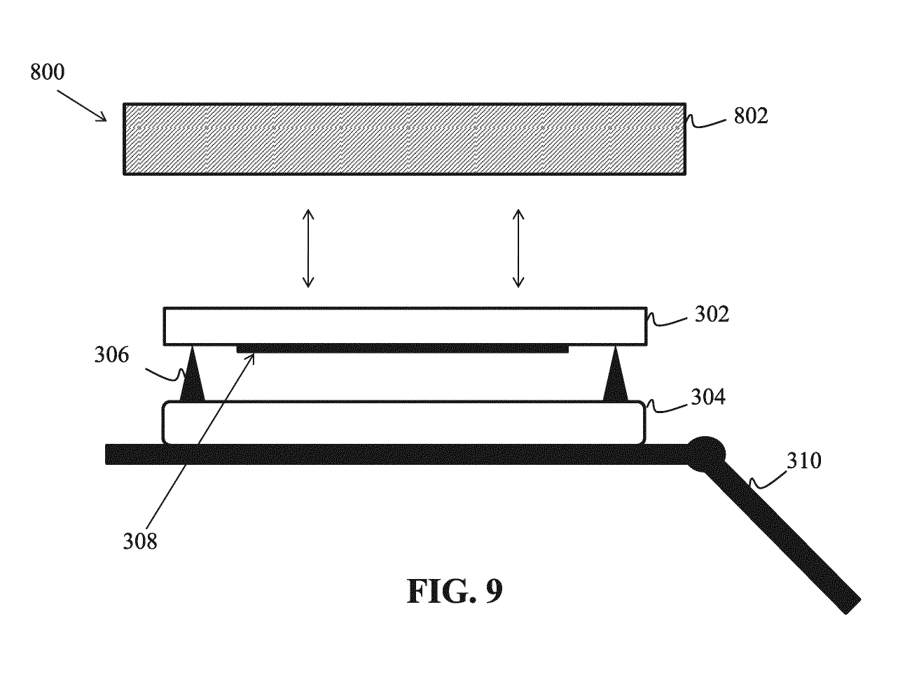

FIG. 9 illustrates another embodiment of cleaning system 800 that includes at least a cleaning layer 802. Cleaning system 800 may include other components as well such as support structures for cleaning layer 802 and/or actuating systems for moving cleaning system 500. In one example, cleaning system 800 may be used for cleaning the backside of EUV reticles.

Patterning device 302 is shown supported by raised features 306 of structure 304 and movable via arm 310 within a lithographic apparatus, according to an embodiment. As such, a backside of patterning device 302 opposite to patterned side 308 may be raised to make contact with cleaning surface 802. Cleaning surface 802 may be, for example, a sticky surface designed to capture particles present on the backside of patterning device 302. Alternatively, patterned side 308 may be placed into contact with cleaning surface 802 to clean particles off of patterned side 308.

Cleaning surface 802 may be a plastic coating that stretches to cover substantially the entire surface area of either the backside or patterned surface 308 of patterning device 302. In one example, cleaning surface 802 is brought into contact with patterning device 302 while, in another example, patterning device 302 is brought into contact with cleaning surface 802. The relative size of cleaning surface 802 allows contact to be made over substantially the entire surface of patterning device 302 during a single contact step. Cleaning surface 802 may include a similar material to layer of tape 502, such as Kapton tape. In an embodiment, cleaning surface 802 leaves behind no residue on the surface of patterning device 302 after contact.

Patterning device 302 and cleaning layer 802 may be brought into and out of contact repeatedly to adequately clean the surface of patterning device 302. In one example, the position of either patterning device 302 or cleaning layer 802 may be slightly shifted between each contacting step to account for any potential irregularities in the contact area between patterning device 302 and cleaning layer 802. Cleaning layer 802 may be easily disposable and replaced with a fresh layer once the original layer becomes less effective at capturing particles.

Patterning device 302 may be brought into contact with cleaning layer 802 after being loaded into a lithographic apparatus for an “initial cleaning.” In another example, patterning device 302 may be removed from a clamp structure within the lithographic apparatus, brought into contact with cleaning layer 802, and reclamped to the clamp structure. In the examples contemplated, various surfaces of patterning device 302 may be cleaned without removing patterning device 302 from a vacuum environment within the lithographic apparatus.

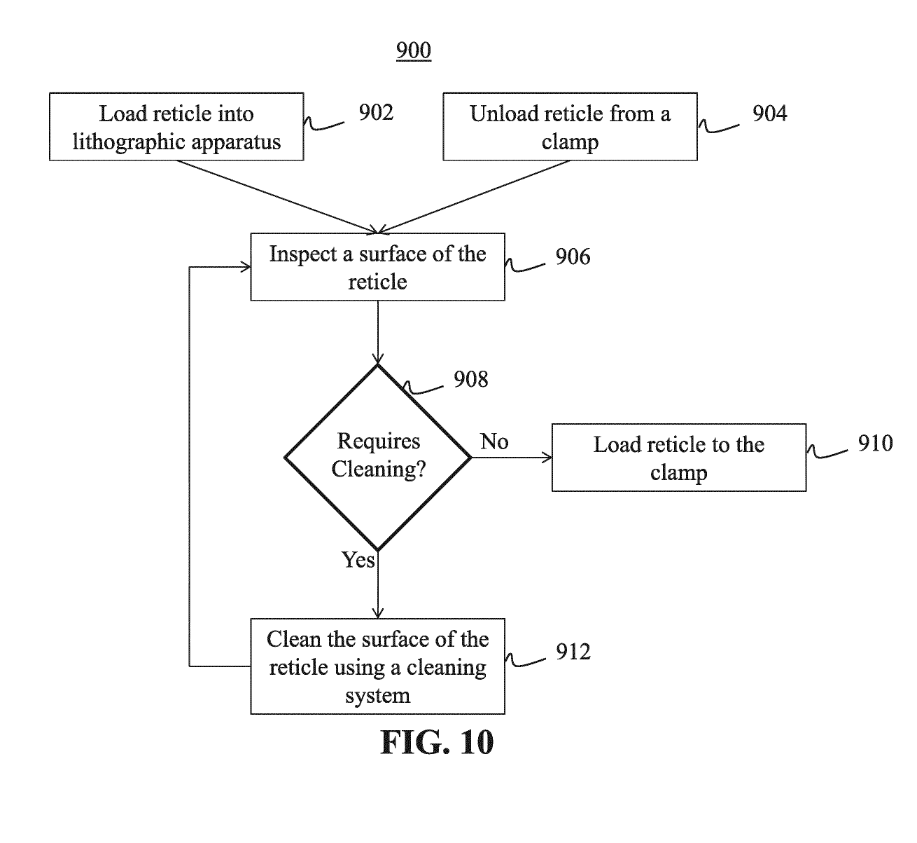

FIG. 10 illustrates a flowchart depicting a method 900 for inspecting and cleaning a patterning device (e.g., a reticle), according to an embodiment. Method 900 may begin at step 902 by loading the reticle into the lithographic apparatus, or method 900 may begin at step 904 by unloading the reticle from a clamp already within lithographic apparatus.

At step 906, the surface of the reticle is inspected to determine the level of particle contamination present on the surface. The backside, patterned side, or both sides of the reticle may be examined. The inspection may be performed via a variety of imaging techniques. For example, a CCD camera or video camera may capture images of the surface for further processing. In other examples, scatterometry and/or interferometry systems may be used to detect surface irregularities caused by any present particles. It should be understood that the scope and spirit of the invention should not be limited to any one inspection technique.

At step 908, a determination is made whether or not the inspected surface(s) of the reticle requires cleaning. This determination may be based on comparing the cleanliness of the inspected surface(s) to a threshold. For example, if a certain percentage of the inspected surface(s) is determined to contain particles, and this percentage is greater than a threshold value, then it would indicate that the surface(s) require cleaning. In another example, if a certain percentage of the inspected surface(s) is determined to be clean, and this percentage is less than a threshold value, then it would indicate that the surface(s) require cleaning. Other comparison techniques for determining whether cleaning should occur or not would be readily apparent to one having skill in the relevant art(s) given the description herein. The threshold value may be stored in, for example, a memory associated with the lithographic apparatus and coupled to a processing device for performing the determination.

If the reticle surface is determined to be clean enough, the reticle is loaded to a clamp, such as, for example, an electrostatic clamp (ESC) at step 910, according to an embodiment. Once the reticle has been clamped, exposures may be carried out using the reticle without any immediate concerns regarding contamination since the reticle surface passed inspection before being clamped.

If the reticle surface is determined to be contaminated, the surface is cleaned at step 912 using any of the various cleaning system embodiments described herein, according to an embodiment. Once the cleaning has been completed, method 900 repeats with step 906 and re-inspects the surface(s) of the reticle.

It is to be appreciated that method 900 may not include all operations shown, or perform the operations in the order shown. For example, method 900 may not include inspection of the reticle surface, but rather, a process of cleaning the surface each time before the reticle is loaded to a chuck regardless of whether it may have surface contamination or not.

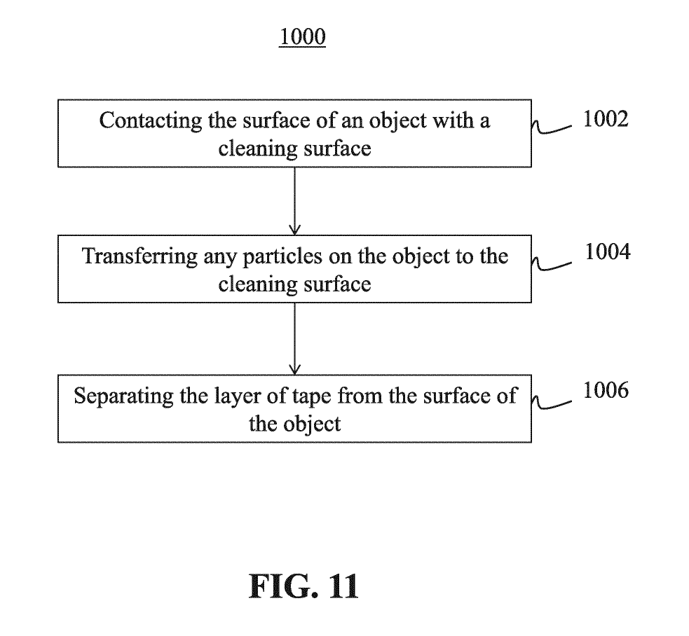

FIG. 11 illustrates a flowchart depicting a method 1000 for removing particles from a surface of an object within a lithographic apparatus, according to an embodiment. The embodiments of cleaning systems 500, 700, or 800 illustrated in FIGS. 5, 7, and 8 may be used in method 1000 to transfer particles from the surface of an object to a cleaning surface, such as layer of tape 502 or cleaning layer 802. It is to be appreciated that method 1000 may not include all operations shown, or perform the operations in the order shown.

Method 1000 begins at step 1002 where the surface of an object is contacted with a cleaning surface. The cleaning surface may be an adhesive surface or charged to electrostatically attract particles on the surface of the object. The object may be, for example, a patterning device or a chuck designed to hold the patterning device. The object may also be a chuck designed to hold a substrate, such as a silicon wafer. The contact may be made by bringing the object to the cleaning surface or visa-versa.

At step 1004, particles on the surface of the object are transferred to the cleaning surface. The transfer may occur due to the physical contact between the surface of the object and the cleaning surface, or may occur due to electrostatic interactions between the particles and the cleaning surface.

At step 1006, the cleaning surface is separated from the surface of the object. After separating, particles that were present on the surface of the object are now captured on the cleaning surface.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the present invention have been described above, it will be appreciated that the present invention may be practiced otherwise than as described. The descriptions above are intended to be illustrative, not limiting. Thus it will be apparent to one skilled in the art that modifications may be made to the present invention as described without departing from the scope of the claims that follow.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A method of removing particles from a surface of an object within a lithographic apparatus, the method comprising:
providing a tape with a cleaning layer such that the tape is stretched between first and second holders;
moving the first and second holders in a first direction to translate the stretched tape towards the surface of the object;
contacting the surface of the object with the tape to transfer the particles on the surface of the object to the tape; and
moving the first and second holders in a second direction different from the first direction to separate the tape with the transferred particles from the surface of the object.

2. The method of claim 1, wherein the object is a patterning device or a chuck.

3. The method of claim 2, wherein the surface of the patterning device is a backside surface of the patterning device.

4. The method of claim 2, wherein the surface of the patterning device is an area adjacent to a patterned surface on the patterning device.

5. The method of claim 1, wherein the moving the first and second holders in a first direction and the moving the first and second holders in a second direction are each automated.

6. The method of claim 1, further comprising:
advancing the tape between the first and second holders to expose a fresh cleaning layer with no particles present for subsequent cleaning.

7. The method of claim 1, wherein the transferring and separating leave substantially no residue from the cleaning layer behind on the surface of the object.

8. The method of claim 1, further comprising:
after separating the tape with the transferred particles from the surface of the object, inspecting the surface of the object to determine a level of surface contamination; and repeating the moving steps and the contacting in response to the level of the surface contamination being above or below a threshold value.

9. The method of claim 1, wherein the providing further comprises:
mounting the tape on a first support holder adjacent the surface of the object, such that the first support holder is configured to support the tape to make contact with the surface of the object for removing particles from the surface of the object.

10. A lithographic apparatus comprising:
an illumination system configured to condition a radiation beam;
a support constructed to hold a patterning device, the patterning device being capable of imparting the radiation beam with a pattern in its cross-section to form a patterned radiation beam;
a substrate table constructed to hold a substrate;
a projection system configured to project the patterned radiation beam onto a target portion of the substrate; and
a cleaning system including a tape with a cleaning layer, such that the tape is stretched between first and second holders, the cleaning system being configured to:
move the first and second holders in a first direction to translate the stretched tape towards a surface of the support or the patterning device,
contact the surface of either the support or the patterning device with the tape to transfer the particles on the surface of the support or the patterning device to the tape; and
move the first and second holders in a second direction different from the first direction to separate the tape with the transferred particles from the surface of the support or the patterning device.

11. The apparatus of claim 10, wherein the surface of the patterning device is an area adjacent to a patterned surface on the patterning device.

12. The apparatus of claim 10, further comprising:
a motor coupled to at least one of the first and second holders and configured to advance the tape subsequent to the cleaning to expose a fresh cleaning layer with no particles present for subsequent cleaning.

13. The apparatus of claim 10, wherein the cleaning layer is configured to capture the particles without leaving residue on the surface of the support or the patterning device.

14. The apparatus of claim 10, wherein the support comprises an electrostatic chuck.

15. A cleaning apparatus configured to capture particles off of a surface of a support or a patterning device in a lithographic apparatus, the cleaning apparatus comprising:
a tape with a cleaning layer;
first and second holders constructed and arranged such that the tape is wound between the first and second holders; and
a support holder configured to support the tape and provide a flat surface of the tape when the tape is stretched over the support holder,
wherein the support holder is further configured to move and thereby translate the tape towards the surface of the support or the patterning device and away from the surface of the support or the patterning device, and
wherein the cleaning layer of the tape is configured to capture the particles without leaving residue on the surface of the support or the patterning device.

16. The cleaning apparatus of claim 15, further comprising:
a motor coupled to at least one of the first and second holders and configured to advance the tape to expose a fresh cleaning layer with no particles present for subsequent cleaning.

17. The cleaning apparatus of claim 15, wherein the support holder is further configured to move laterally along the surface of the support or the patterning device while exposing the tape with no particles present on the tape, and transfer particles present on the surface of the support or the patterning device to the cleaning layer of the tape.

18. The cleaning apparatus of claim 15, wherein the support holder is further configured to move the tape away from the surface of the support or the patterning device before advancing the tape to expose a fresh cleaning layer with no particles present for subsequent cleaning.
